(19) United States
(12) Patent Application Publication
(10) Pub. No.: US 2005/0202976 A1
(43) Pub. Date: Sep. 15, 2005

(54) Apparatus for use in nmr system

(76) Inventor: Neil Killoran, Oxon (GB)

Correspondence Address: STAAS & HALSEY LLP, SUITE 700, 1201 NEW YORK AVENUE, N.W., WASHINGTON, DC, 20005, US

(21) Appl. No.: 10/415,551

(22) PCT Filed: Sep. 6, 2002
(86) PCT No.: PCT/GB02/04076

§ 371 Date: Oct. 14, 2003

(30) Foreign Application Priority Data
Sep. 6, 2001 (GB) 0121603.5

(51) Int. Cl. H01L 39/00

(52) U.S. Cl. 505/200

(57) ABSTRACT

Apparatus for use in a nuclear magnetic resonance system comprises a cryostat including a coolant vessel (3) containing coolant such as liquid helium (4) and a refrigerator (8) for cooling coolant in the coolant vessel, the cryostat surrounding a sample space (10). A superconducting coil (2) is located in the coolant vessel (3) for generating a Bₒ magnetic field in the sample space (10). Rf magnectic field generating and receiving apparatus (14)is located adjacent the sample space. A closed coolant loop (16) contains coolant such as helium which is cooled by the refrigerator (8), and a pump (20) for circulating the coolant around the loop. The coolant loop (16) is thermally coupled with the rf apparatus (14) so as to cool the rf apparatus.

The invention relates to apparatus for use in a nuclear magnetic resonance (NMR) system, for example a system for enabling NMR experiments to be performed on a fixed or flowing sample.

In order to carry out a nuclear magnetic resonance (NMR) experiment, it is necessary to generate a high strength magnetic field with good stability and uniformity onto which further magnetic fields such as gradients can be superimposed. Conventionally, the high strength magnetic field is generated by a magnet formed by electrical coils held in a superconducting condition by immersing the coils, typically wound with NbTi or other superconducting wire, in liquid helium located in a coolant vessel in a cryostat. The cryostat is built to surround a central bore or sample space into which a sample to be inspected is inserted. On the radially inner face of that bore one or more pulsed field gradient (PFG), shim and radio frequency (RF) coils are provided which conventionally operate at room temperature.

Conventionally, these shim and combined RF and gradient coils have been provided as separate removable items so that they can be changed as required in accordance with the sample and NMR experiment to be performed.

U.S. Pat. No. 4,652,824 discloses a cryostat containing a superconducting magnet and in which gradient and rf coils are located in a vessel just radially outward of the sample space, the gradient coils being cooled as a result of liquid nitrogen being circulated through the gradient coil support.

This approach improves the performance of the rf coils, in particular signal to noise ratio, but has the disadvantage that there is significant loss of coolant.

In accordance with the present invention, apparatus for use in a NMR system comprises a cryostat including a coolant vessel containing coolant, and a refrigerator for cooling coolant in the coolant vessel, the cryostat surrounding a sample space; a superconducting coil in the coolant vessel for generating a B₀ magnetic field in the sample space; rf magnetic field generating and receiving apparatus located adjacent the sample space; and a closed coolant loop containing coolant which is cooled by the refrigerator, and a pump for circulating the coolant around the loop, the coolant loop being thermally coupled with the rf apparatus so as to cool the rf apparatus.

We have recognised that in some situations, particularly industrial processes, it is not necessary to regularly change the rf apparatus (coil or antenna) configuration and thus this apparatus can be (relatively) permanently mounted within the main magnet cryostat. In addition, this enables the rf apparatus to be cooled utilizing a closed coolant loop which then has the benefit that there is no evaporation and resupply of coolant to the coolant loop. Finally, a single refrigerator is provided to cool both the coolant loop and coolant in the coolant vessel. With all these features, a much simpler and commercially useful product is achieved which does not require coolant replacement other than conventional servicing at perhaps yearly intervals.

Typically, the refrigerator is directly coupled to the coolant loop via a heat exchanger although more indirect thermal coupling via radiation shields or the like is possible.

Preferably, one or more gradient coils are provided also thermally coupled to the coolant loop.

The gradient coils could be located within the sample space i.e. typically at room temperature with the coolant loop passing out from the cryostat wall. However, preferably, the gradient coil(s) are located within the cryostat.

Although the rf apparatus and gradient coils, if provided could simply be wound around a pipe carrying the coolant in the loop, preferably the apparatus (and coils) are thermally coupled to the coolant loop via a heat exchanger.

Conveniently, the rf apparatus and magnetic field gradient coil(s), if provided, are located within an outer vessel of the cryostat. This leads to ease of manufacture. By “outer” we mean adjacent the sample space.

Conveniently, the outer vessel is an evacuated vessel and although in some cases it may form a permanent part of the cryostat, it is particularly convenient if the outer vessel is detachable from the rest of the cryostat without the need to purge the coolant vessel. This allows the rf apparatus (and gradient coils) to be serviced or changed as necessary without the need to purge the remainder of the cryostat.

Conventionally, shim coils are located within the sample space at room temperature but in a further preferred approach, one or more shim coils are located within the cryostat. This again serves to protect the shim coils from external interference.

The shim coil(s) may be located in the outer vessel or within the cryostat separate from the outer vessel. The latter arrangement being particularly suitable if the outer vessel is detachable from the rest of the cryostat.

It is possible to take further advantage of the presence of a closed coolant loop to cool other parts of the apparatus. For example, the apparatus may further comprise rf apparatus control electronics thermally coupled with the coolant loop. Typically, this control electronics will be located downstream in the direction of coolant flow with respect to the rf apparatus and thus be held at a higher temperature than the rf apparatus.

The rf apparatus may comprise one or more rf coils or antennae in a conventional manner.

The coolant is preferably helium thus enabling the superconducting coils to be cooled to 4.2K and rf apparatus to be cooled between 4.2 and 25K.

The refrigerator is preferably a two or three stage cooler and may comprise a Gifford-McMahon or pulse tube refrigerator. The pulse tube refrigerator is preferred due to its much lower vibration levels. Where A two or three stage refrigerator is used, the first (higher temperature) stage can be used to cool a radiation shield in a conventional manner.

Some examples of apparatus in accordance with the invention will now be described with reference to the accompanying drawings, in which:

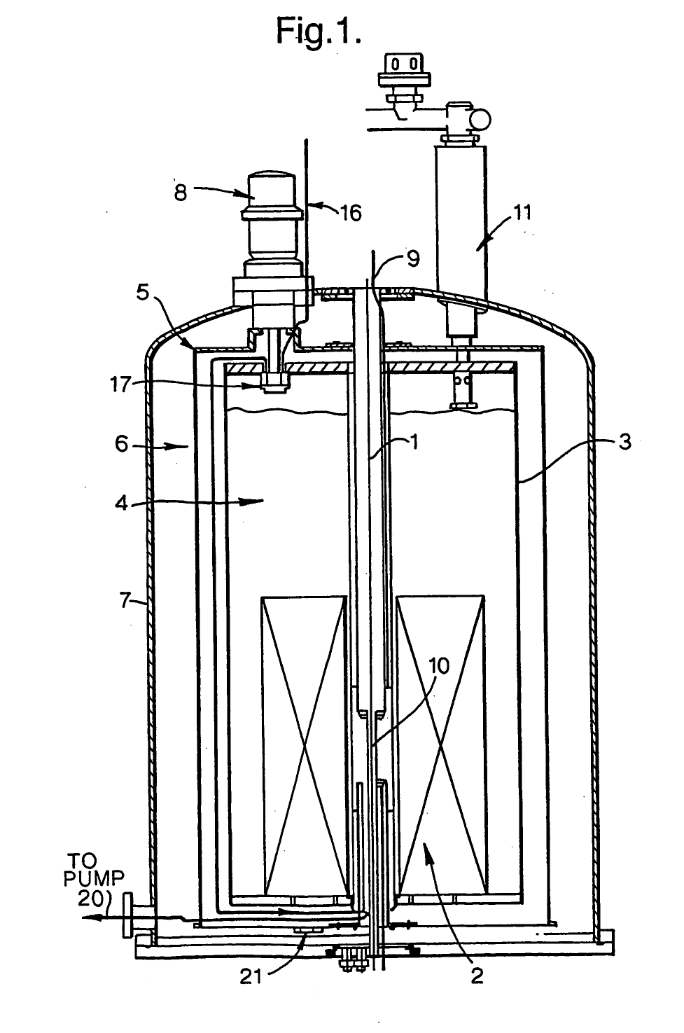

FIG. 1 is a schematic, longitudinal section through a first example;

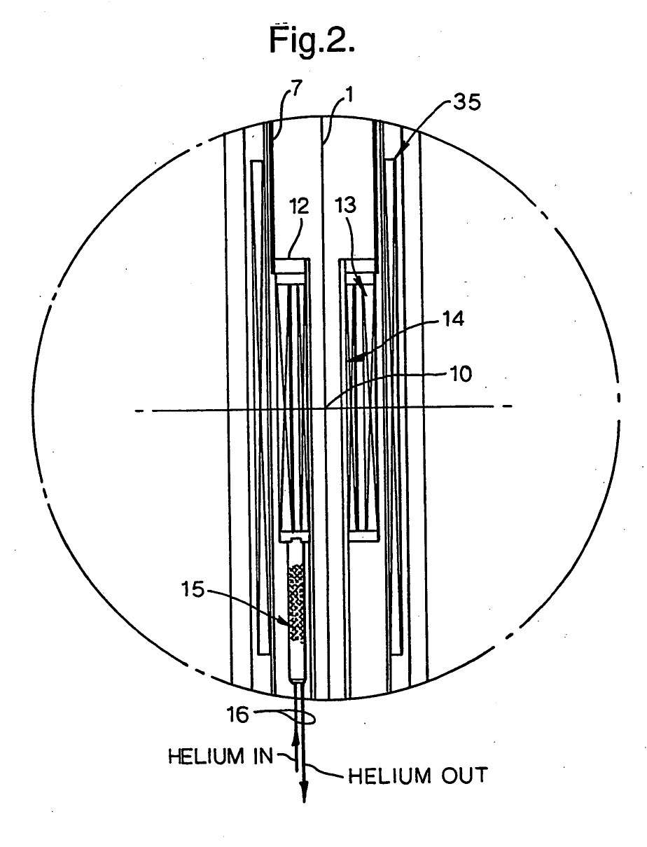

FIG. 2 is an enlarged view of the coils of the FIG. 1 example;

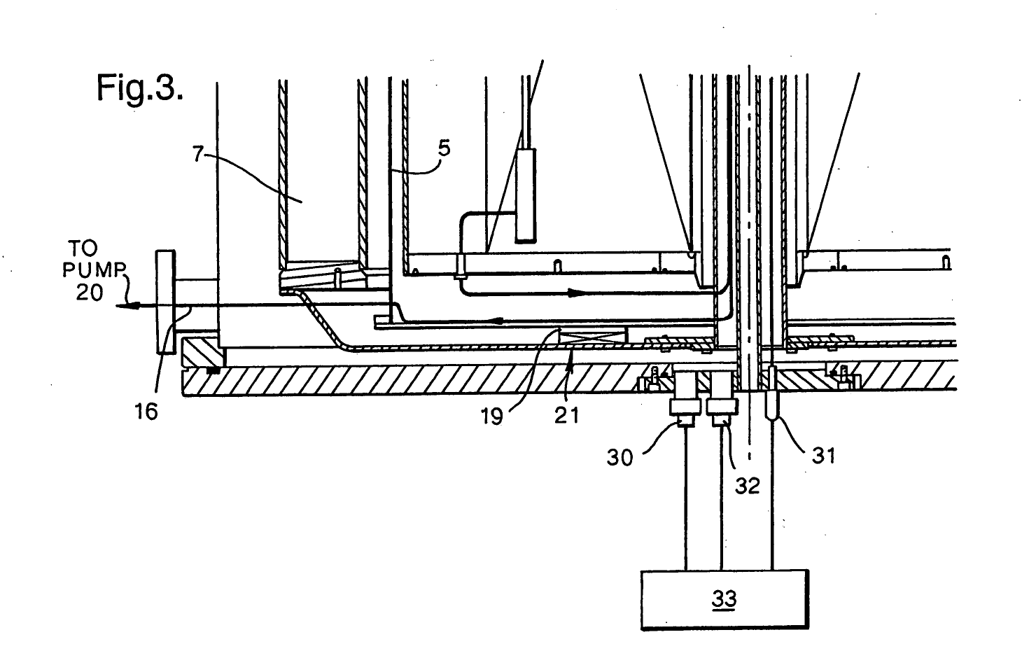

FIG. 3 is an enlarged view of part of the base of the FIG. 1 example;

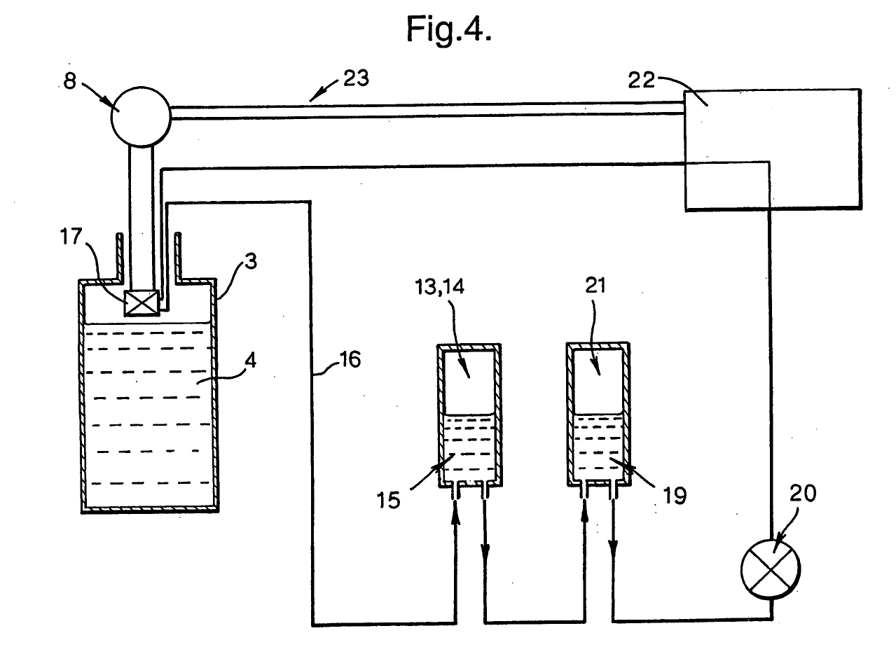

FIG. 4 illustrates the cooling circuit of the FIG. 1 example in more detail; and,

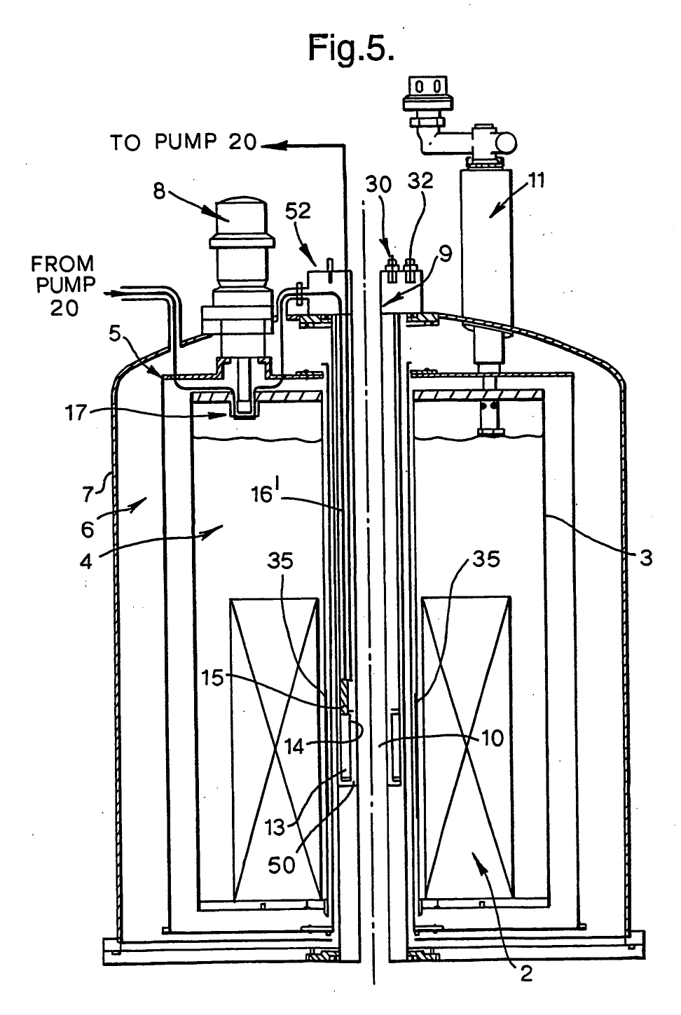

FIG. 5 is a view similar to FIG. 1 but of a second example.

FIG. 1 illustrates part of a first example of the apparatus, the apparatus being substantially symmetric about a centre line 1. The assembly includes an annular, main magnet 2 located within a coolant vessel 3 of a cryostat, the vessel containing liquid helium 4 initially supplied through an access neck 11. A radiation shield 5 surrounds the liquid helium bath 3 and these components are housed within an outer vacuum vessel 7. An evacuated space 6 is defined between the shield 5 and the wall of the vessel 7.

The wall of the liquid helium vessel 3 and the radiation shield 5 are cooled by a refrigerator 8 which may be a Gifford-McMahon or pulse tube cooler. As is conventional, these are two or three stage devices which cool the radiation shield 5 to a temperature of about 77K and the liquid helium to about 4.2K.

The vacuum chamber 7 has a central bore tube 9 within which a probe (not shown) can be removably inserted, the probe carrying a sample at its lower end, so as to locate the sample at a position 10 at the centre of the magnet 2, the position 10 defining a sample space at room temperature. (In other applications, a (liquid or gas) sample is flowed through the bore tube.)

As can be seen in FIG. 2, the vacuum vessel 7 includes a step 12 which thus narrows the central bore; and located adjacent the bore behind the walls of the vacuum vessel 7 (and hence within the cryostat) are positioned a set of pulse field gradient coils 13 and RF coils 14. These coils will have a conventional construction and thus will not be described in any detail. The coils are coupled with a heat exchanger 15 including heater and temperature sensors (not shown) for controlling temperature in the range 4.2-25K.

As can be more clearly understood from FIG. 4, the heat exchanger 15 is coupled in a closed coolant loop 16 formed by a number of coolant carrying tubes which contain helium. The coolant loop 16 passes through a heat exchanger 17 located within the coolant vessel 3. The heat exchanger 17 is cooled by the pulsed tube refrigerator 8. From the heat exchanger 17, liquid helium passes along the loop to the heat exchanger 15 to which the rf and PFG coils 14,13 are connected so that these coils are then cooled. The liquid helium passes on to a further heat exchanger 19 which is mounted to the shield 5 and to which rf preamp electronics 21 are coupled so as to be cooled to about 77K.

The loop then passes out of the cryostat to a pump 20 where it is pumped up to a pulse tube refrigerator gas flow control system of conventional form 22. From there the liquid helium in gaseous form flows back to the heat exchanger 17 for cooling. Where the coolant loop extends outside the cryostat, all external pipework would need vacuum insulation, thermo shielding and low heat loss couplings.

As can be seen also in FIG. 4, the pulse tube refrigerator gas flow control system 22 is coupled directly with the refrigerator 8 via a second closed loop helium circuit 23 in a conventional manner.

It will be noted, therefore, that the refrigerator 8 not only cools liquid helium 4 in the vessel 3 but also, via the heat exchanger 17, helium within the closed loop 16.

Sets of shim coils 35 are positioned radially outwardly of the rf and PFG coils 14,13 coupled with the shield 5. In other arrangements (not shown), the shim coils 35 could be located within the bore 9 and thus at room temperature.

At the base of the apparatus, as can be seen in FIG. 3, rf electrical connections 30, rf tune and match connections 31, and shim coil electrical connections 32 are provided connected to a processing system 33 which enables the shim coils and rf coils to be controlled and detects rf signals received by the rf coils for use in subsequent NMR processing in a conventional manner.

It will be noted that the rf coils 14, PFG coils 13 and shim coils 35 are located within the cryostat and thus are not readily interchangeable. However, through suitable heat exchange they are cooled to an extent sufficient to significantly improve their performance and in particular signal to noise ratio.

FIG. 5 illustrates a second example of apparatus according to the invention. The structure of the cryostat in this example is similar to the cryostat of FIG. 1 and so the same reference numerals have been used to indicate similar components and these will not be described further. The main difference lies in the provision of an additional vacuum vessel 50 radially inwardly of the remainder of the cryostat and which contains the rf and gradient coils 13,14. As before, these are coupled with a heat exchanger 15 which is thermally coupled to a helium coolant, closed loop 16′. As can be seen in FIG. 5, the coolant loop 16′ extends upwardly through the vessel 50, exits from the top of the cryostat as shown at 52 with the exhaust line passing to the pump 20 (not shown). The input line from the pump 20 passes into the cryostat to the heat exchanger 17.

In this case, the electrical connections 30,32 are provided at the top of the cryostat while the rf electronics 21 are connected via the heat exchanger 19 (not shown in FIG. 5) with the coolant loop 16′ again at the top of the cryostat.

If it is desired to change the coils 13,14 or carry out other maintenance, the vessel 50 is brought to room pressure and the coolant line 16′ is purged and disconnected at 52 allowing the coils 13,14 and heat exchanger 15 together with those conduits of the coolant line 16′ within the vessel 50 to be removed. It will be noted, however, that there is no need to purge the liquid helium 4 while these changes are taking place.

1. Apparatus for use in a nuclear magnetic resonance system, the apparatus comprising a cryostat including a coolant vessel containing coolant, and a refrigerator for cooling coolant in the coolant vessel, the cryostat surrounding a sample space; a superconducting coil in the coolant vessel for generating a B₀ magnetic field in the sample space; rf magnetic field generating and receiving apparatus located adjacent the sample space; and a closed coolant loop containing coolant which is cooled by the refrigerator, and a pump for circulating the coolant around the loop, the coolant loop being thermally coupled with the rf apparatus so as to cool the rf apparatus.

2. Apparatus according to claim 1, wherein the refrigerator is directly coupled to the coolant loop via a heat exchanger.

3. Apparatus according to claim 1 or claim 2, further comprising one or more gradient coils also thermally coupled to the coolant loop.

4. Apparatus according to claim 3, wherein the rf apparatus and magnetic field gradient coil(s), if provided, are thermally coupled to the coolant loop via a heat exchanger.

5. Apparatus according to any of the preceding claims, wherein the rf apparatus and magnetic field gradient coil(s), if provided, are located within an outer vessel of the cryostat.

6. Apparatus according to claim 5, wherein the outer vessel is an evacuated vessel.

7. Apparatus according to claim 4 or claim 5, wherein the outer vessel is detachable from the rest of the cryostat without the need to purge the coolant vessel.

8. Apparatus according to any of the preceding claims, further comprising one or more shim coils located within the cryostat.

9. Apparatus according to according to claim 8, when dependent on any of claims 5 to 7, wherein the shim coil(s) is located in the outer vessel.

10. Apparatus according to according to claim 8, when dependent on any of claims 5 to 7, wherein the shim coil(s) is located within the cryostat separate from the outer vessel.

11. Apparatus according to any of the preceding claims, further comprising rf apparatus control electronics thermally coupled with the coolant loop.

12. Apparatus according to claim 11, wherein the rf apparatus control electronics is thermally coupled with the coolant loop downstream in the direction of coolant flow from the rf apparatus.

13. Apparatus according to any of the preceding claims, wherein the rf apparatus comprises one or more rf coils.

14. Apparatus according to any of the preceding claims, wherein the coolant is helium.

15. Apparatus according to any of the preceding claims, wherein the refrigerator comprises a Gifford-McMahon or pulse tube refrigerator.

16. An NMR system including apparatus according to any of the preceding claims; a processing system coupled with the rf apparatus and gradient coils, if provided; and a sample support which can be inserted into the apparatus when carrying a sample to position the sample in the sample space.
